(19) United States
(12) Patent Application Publication
(10) Pub. No.: US 2025/0246526 A1
(43) Pub. Date: Jul. 31, 2025

(54) SEMICONDUCTOR MODULE

(71) Applicant: FUJI ELECTRIC CO., LTD., Kawasaki-shi (JP)

(72) Inventor: Kousuke KOMATSU, Matsumoto-city (JP)

(73) Assignee: FUJI ELECTRIC CO., LTD., Kawasaki-shi, Kanagawa (JP)

(21) Appl. No.: 18/961,607

(22) Filed: Nov. 27, 2024

(30) Foreign Application Priority Data
Jan. 29, 2024 (JP) 2024-010779

(51) Int. Cl. H01L 23/498

(52) U.S. Cl. CPC H01L 23/49811

(57) ABSTRACT

A semiconductor module includes an insulating substrate disposed on a base and provided with a semiconductor chip, a frame-shaped housing surrounding the substrate, and external terminals electrically connected to the chip and each having a portion disposed in the housing and a portion protruding from the housing, wherein the substrate includes an insulating board and a conductor pattern disposed on the board and including a conductor joined to the chip, wherein at least one of the terminals includes a pin extending toward an outside of the housing along a thickness-direction of the substrate, a leg extending toward an inside of the housing along a direction intersecting an extension-direction of the pin, and a connector extending from the pin toward the substrate along the thickness-direction of the substrate, and wherein the connector is in contact with the conductor pattern and receives compression force from the substrate and the housing.

### CROSS REFERENCE TO RELATED APPLICATION

This Application is based on, and claims priority from, Japanese Patent Application No. 2024-010779, filed on Jan. 29, 2024, the entire contents of which are incorporated herein by reference.

### BACKGROUND

### Technical Field

The present disclosure relates to semiconductor modules.

### Related Art

A semiconductor module, such as a power semiconductor module, includes an insulating substrate provided with a semiconductor chip, a housing for accommodating the insulating substrate, and a plurality of external terminals electrically connected to the semiconductor chip, as described in Japanese Patent Application Laid-Open Publication No. 2017-005129, Japanese Patent Application Laid-Open Publication No. 2017-92388, Japanese Patent Application Laid-Open Publication No. 2000-208686, and WO 2021/085216, for example.

In a module described in Japanese Patent Application Laid-Open Publication No. 2017-005129, each main terminal of a plurality of main terminals (external terminals) fixed to a housing is electrically connected to either a semiconductor chip or an insulating substrate via a bonding wire in the housing. In the module described in Japanese Patent Application Laid-Open Publication No. 2017-005129, the insulating substrate is disposed on a base plate made of a material with excellent thermal conductivity such as a copper material or an aluminum material, and an insulator with high thermal radiation is interposed between the base plate and a main terminal that is any one of the plurality of main terminals so as to reduce thermal resistance of an area between the base plate and the main terminal. The insulator with high thermal radiation is formed by insert molding to be fixed to the housing together with the main terminal.

However, in the module described in Japanese Patent Application Laid-Open Publication No. 2017-005129, since many bonding wires connecting the plurality of main terminals to the insulating substrate are required, it is difficult to reduce a size of the housing and to provide the insulating substrate with a large semiconductor chip having a large rated current.

### SUMMARY

In view of the circumstances described above, an object of one aspect according to this disclosure is to reduce a size of a semiconductor module and to increase a rated current of the semiconductor module.

To solve the above problem, a semiconductor module according to an aspect of this disclosure includes a base plate; an insulating substrate disposed on a surface of the base plate and provided with a semiconductor chip; a housing having a shape of a frame surrounding the insulating substrate; and a plurality of external terminals each having a portion disposed in the housing and a portion protruding from the housing, the plurality of external terminals being electrically connected to the semiconductor chip, wherein the insulating substrate includes an insulating board; and a conductor pattern disposed on a surface of the insulating board and including a conductor joined to the semiconductor chip, wherein at least one external terminal of the plurality of external terminals includes a pin extending toward an outside of the housing along a direction of thickness of the insulating substrate; a leg extending toward an inside of the housing along a direction intersecting a direction of extension of the pin; and a connector extending from the pin toward the insulating substrate along the direction of thickness of the insulating substrate, and wherein the connector is in contact with the conductor pattern in a state in which the connector receives compression force from the insulating substrate and the housing.

### BRIEF DESCRIPTION OF THE DRAWINGS

FIG. 1 is an exploded perspective view of a semiconductor module according to an embodiment.

FIG. 2 is a cross section of the semiconductor module according to this embodiment.

FIG. 3 is another cross section of the semiconductor module according to this embodiment.

FIG. 4 is yet another cross section of the semiconductor module according to this embodiment.

FIG. 5 is a perspective view of an external terminal according to this embodiment.

FIG. 6 is a diagram explaining an example of a method for producing the external terminal.

FIG. 7 is a cross section of a semiconductor module according to a first modification.

### DESCRIPTION OF EMBODIMENTS

An embodiment according to this disclosure will be described with reference to the drawings. In the drawings, dimensions and scales of elements may differ from those of actual products, and some elements may be shown schematically to facilitate understanding. The scope of this disclosure is not limited to this embodiment described below unless the following explanation includes a description that specifically limits the scope of this disclosure.

### 1. Embodiment

### 1-1. Overall Configuration of Semiconductor Module

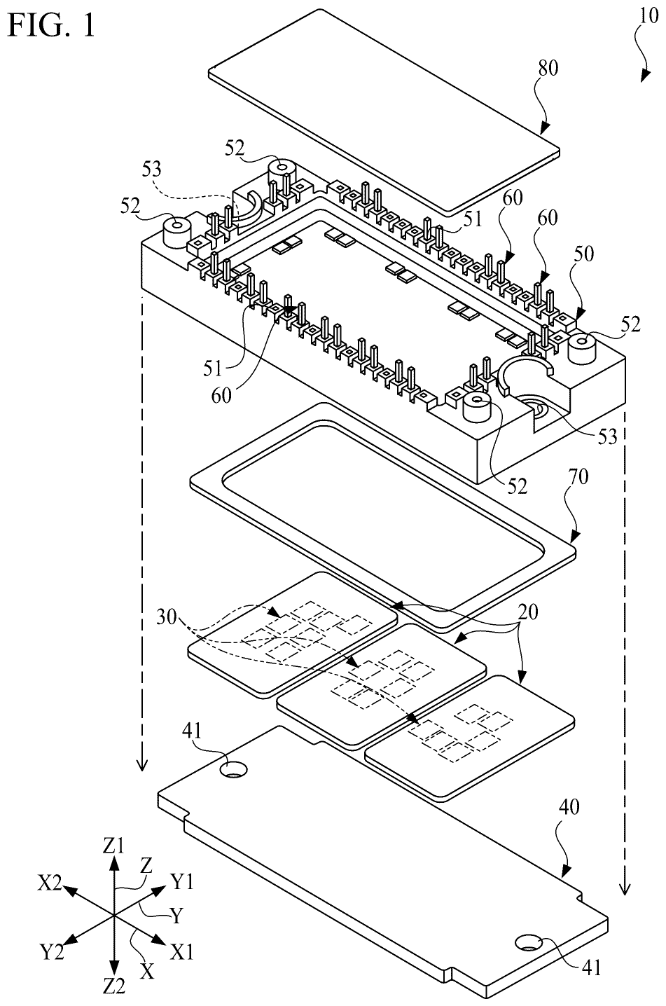

FIG. 1 is an exploded perspective view of a semiconductor module 10 according to an embodiment. The semiconductor module 10 is a power module such as an insulated gate bipolar transistor (IGBT) module. The semiconductor module 10 is used, for example, to power control a device such as an inverter or a rectifier. The inverter or the rectifier may be provided to an apparatus such as a rail vehicle, an automobile, or a household electrical appliance.

As shown in FIG. 1, the semiconductor module 10 includes a plurality of insulating substrates 20, a plurality of semiconductor chips 30, a base plate 40, a housing 50, a plurality of external terminals 60, a spacer 70, and a lid 80. In FIG. 1, the plurality of insulating substrates 20 and the plurality of semiconductor chips 30 are schematically shown.

First, an outline of each element of the semiconductor module 10 will be described with reference to FIG. 1. For convenience, in the following description, an X-axis, a Y-axis, and a Z-axis are defined that are perpendicular to one another. The Z-axis is an axis parallel to a direction of thickness of the semiconductor module 10. In the following description, a direction along the X-axis is referred to as a direction X1, and a direction opposite to the direction X1 is referred to as a direction X2. A direction along the Y-axis is referred to as a direction Y1, and a direction opposite to the direction Y1 is referred to as a direction Y2. A direction along the Z-axis is referred to as a direction Z1, and a direction opposite to the direction Z1 is referred to as a direction Z2. The relationship between each of these directions and the vertical direction is not particularly limited, and the relationship may be freely selected. In the following description, a view in a direction along the Z-axis may be referred to as a “plan view.”

Each of the plurality of insulating substrates 20 is a substrate such as a direct copper bonding (DCB) substrate or a direct bonded aluminum (DBA) substrate. An insulating substrate 20, which is any one of the plurality of insulating substrates 20, has two surfaces. One surface of the two surfaces of the insulating substrate 20 is provided with two or more semiconductor chips 30 among the plurality of semiconductor chips 30, and the other surface of the two surfaces of the insulating substrate 20 is joined to the base plate 40. In an example shown in FIG. 1, a direction of thickness of the insulating substrate 20 is the direction along the Z-axis. A surface of the insulating substrate 20 facing in the direction Z1 is provided with the two or more semiconductor chips 30. A surface of the insulating substrate 20 facing in the direction Z2 is joined to the base plate 40. As described above, the insulating substrate 20 is disposed on a surface of the base plate 40. The insulating substrate 20 is provided with at least one semiconductor chip 30. It should be noted that the number of semiconductor chips 30 provided to the insulating substrate 20 is freely selected. In addition, the number of insulating substrates 20 included in the semiconductor module 10 is not limited to the example shown in FIG. 1, and it may be two or less, or may be four or more.

At least one of the two or more semiconductor chips 30 provided to the insulating substrate 20 is a power semiconductor chip such as IGBT. In this embodiment, the insulating substrate 20 is provided with the two or more semiconductor chips 30 that include not only a switching element such as an IGBT, but also a control chip for controlling operation of the power semiconductor chip. A back surface of the switching element is provided with an input electrode 30a, which is either a drain electrode or a collector electrode. A front surface of the switching element is provided with an output electrode 30b, which is either a source electrode or an emitter electrode, and a control electrode 30c, which is a gate electrode. Alternatively, the insulating substrate 20 may be further provided with an element such as a freewheeling diode (FWD) that allows a load current to return. It should be noted that the semiconductor chip 30 that functions as the control chip may be provided, or may be omitted, as appropriate. In FIG. 1, a semiconductor chip 30 that is any one of the two or more semiconductor chips 30 is shown by a long-dash, double short-dash line. However, the arrangement of the two or more semiconductor chips 30 disposed on the insulating substrate 20 is not limited to the example shown in FIG. 1, and it may be freely selected.

The base plate 40 is a plate-shaped member for dissipating heat. The base plate 40 is made of a copper material, an alloy of copper, an aluminum material, or an alloy of aluminum. The base plate 40 has high thermal conductivity. The base plate 40 dissipates heat conducted from the plurality of semiconductor chips 30. The base plate 40 further has high electrical conductivity. The base plate 40 is electrically connected to a reference potential line such as a ground potential line. The base plate 40 is not limited to a metallic plate as long as the base plate 40 has high thermal conductivity. The base plate 40 may be made of an insulator such as a ceramic material.

In the example shown in FIG. 1, a direction of thickness of the base plate 40 is the direction along the Z-axis. The base plate 40 has a surface facing in the direction Z1 and a surface facing in the direction Z2. The surface of the base plate 40 facing in the direction Z1 is provided with the plurality of insulating substrates 20. The surface of the base plate 40 facing in the direction Z2 is joined to a heat dissipating member such as heat dissipating fins (not shown). As viewed in the direction along the Z-axis, the base plate 40 is shaped to have a pair of long sides extending in the direction along the X-axis and a pair of short sides extending in the direction along the Y-axis. The base plate 40 is provided with a mounting hole 41 in a vicinity of each of the short sides. The mounting hole 41 is a through hole used to screw the heat dissipating member such as heat dissipating fins (not shown) to the base plate 40, for example. In plan view, the shape of the base plate 40 is not limited to the example shown in FIG. 1 and may be freely selected. The base plate 40 may be replaced with two or more base plates 40. It should be noted that the mounting hole 41 may be provided, or may be omitted, as appropriate. The heat dissipating member such as heat dissipating fins may be integrally formed together with the base plate 40.

The housing 50 is a frame-shaped member for accommodating the plurality of insulating substrates 20 and the plurality of semiconductor chips 30. The housing 50 has a shape of a frame surrounding the plurality of insulating substrates 20 and the plurality of semiconductor chips 30. The housing 50 is substantially an insulator. The housing 50 is made of a resin material such as a polyphenylene sulfide (PPS) material or a polybutylene terephthalate (PBT) material. The resin material may include an inorganic filler such as an alumina material or a silica material so as to improve mechanical strength of the housing 50 or so as to reduce a thermal expansion coefficient of the housing 50.

The housing 50 is provided with a plurality of terminal holes 51 arranged along a circumferential direction of the housing 50. A terminal hole 51 that is any one of the plurality of terminal holes 51 is a hole into which one of the plurality of external terminals 60 can be inserted. The terminal hole 51 passes through the housing 50.

In the example shown in FIG. 1, a direction of thickness of the housing 50 is the direction along the Z-axis. The terminal hole 51 extends in the direction along the Z-axis. As viewed in the direction along the Z-axis, the housing 50 is externally shaped to have a pair of long sides extending in the direction along the X-axis and a pair of short sides extending in the direction along the Y-axis. In addition, the housing 50 is provided with a plurality of holes 52 and a plurality of holes 53. A hole 52 that is any one of the plurality of holes 52 is a hole used to screw a substrate (not shown) to be provided with the semiconductor module 10 to the housing 50. A hole 53 that is any one of the plurality of holes 53 is a through hole that is used together with the mounting hole 41 described above to screw the heat dissipating member such as heat dissipating fins (not shown) to the base plate 40. The shape of the housing 50 is not limited to the example shown in FIG. 1 and may be freely selected. It should be noted that the hole 52 and the hole 53 may be provided, or may be omitted, as appropriate.

In this embodiment, the number of terminal holes 51 of the housing 50 is greater than the number of external terminals 60. The plurality of terminal holes 51 includes a first plurality of terminal holes 51, the number of which is equal to the number of external terminals 60, and a second plurality of terminal holes 51 other than the first plurality of terminal holes 51. In each of the first plurality of terminal holes 51, an external terminal 60 among the plurality of external terminals 60 is inserted. In each of the second plurality of terminal holes 51, no external terminal 60 is inserted. The housing 50, in which the number of terminal holes 51 is greater than the number of external terminals 60, is applicable for use with various semiconductor modules that have different terminal locations. The number of terminal holes 51 and the arrangement of the terminal holes 51 are not limited to the example shown in FIG. 1. The number of terminal holes 51 and the arrangement of the terminal holes 51 may each be freely selected. The number of terminal holes 51 may be equal to the number of external terminals 60.

The plurality of external terminals 60 are terminals for electrically connecting the plurality of semiconductor chips 30 to the substrate (not shown) to be provided with the semiconductor module 10. The plurality of external terminals 60 each have a portion, which is disposed in a corresponding terminal hole 51 among the plurality of terminal holes 51 of the housing 50, and a portion protruding from the housing 50. The plurality of external terminals 60 are electrically connected to the plurality of semiconductor chips 30. Each of the plurality of external terminals 60 is made of a metallic material such as a copper material, an alloy of copper, an aluminum material, an alloy of aluminum, or an alloy of iron, for example. Each of the plurality of external terminals 60 may have a plated surface such as a surface plated with Sn or a surface plated with Sn-Cu, for example.

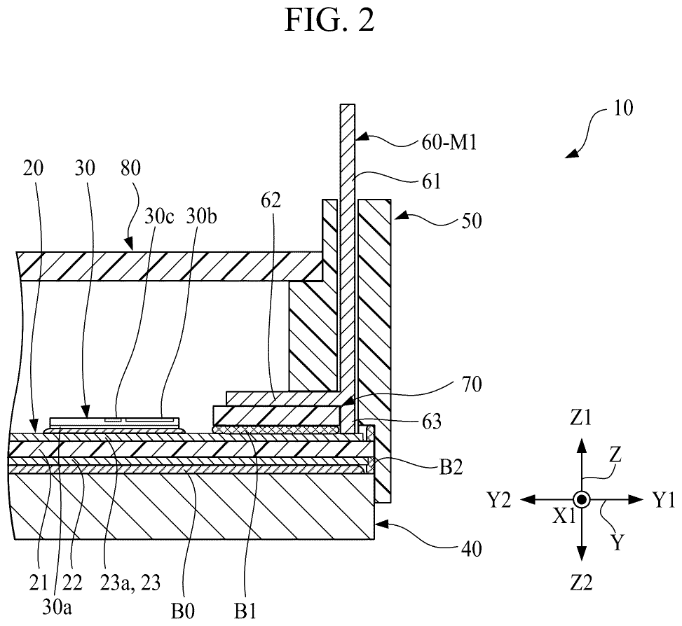

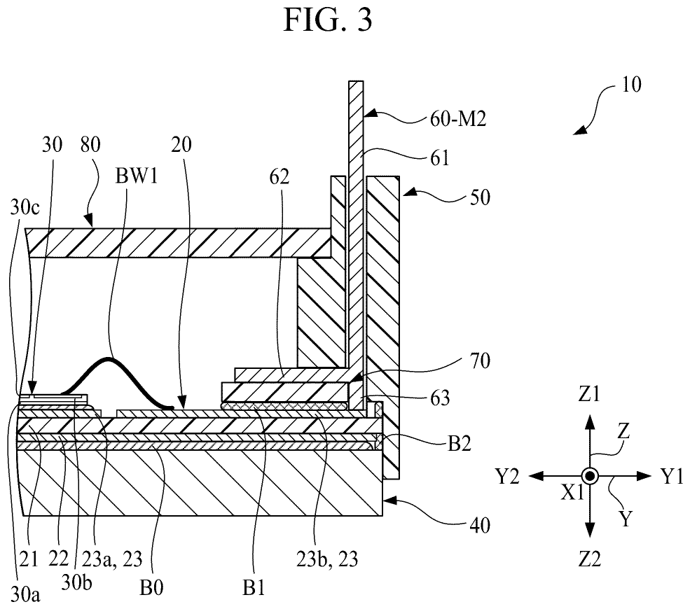

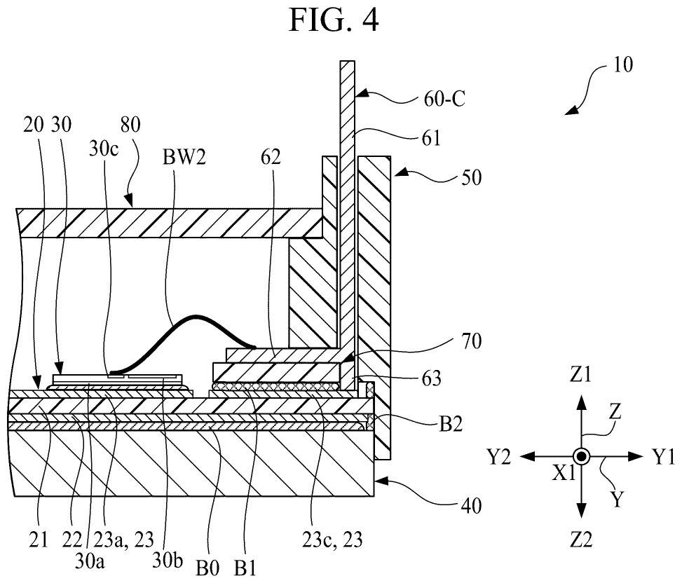

The plurality of external terminals 60 included in the semiconductor module 10 includes a first plurality of external terminals 60 and a second plurality of external terminals 60 other than the first plurality of external terminals 60. The first plurality of external terminals 60 are main terminals through each of which a main current flows. The second plurality of external terminals 60 are control terminals for controlling operation of the plurality of semiconductor chips 30. A main terminal of any one of the main terminals is an external terminal 60-M shown in FIG. 2 or FIG. 3 described below. A control terminal of any one of the control terminals is an external terminal 60-C shown in FIG. 4 described below. The external terminal 60 will be described in detail below with reference to FIG. 2 to FIG. 6.

The spacer 70 is an insulating frame-shaped member interposed between the housing 50 and the plurality of insulating substrates 20. The spacer 70 functions to hold the plurality of external terminals 60 toward the housing 50 and to ensure electrical insulation between the plurality of external terminals 60 and the plurality of insulating substrates 20. The spacer 70 is substantially an insulator. For example, the spacer 70 is made of a resin material such as a PPS material or a PBT material, as is the housing 50. The resin material may include an inorganic filler such as an alumina material or a silica material to improve mechanical strength of the spacer 70. The material contained in the spacer 70 is not limited to a resin material. For example, the material contained in the spacer 70 may be a ceramic material.

In the example shown in FIG. 1, a direction of thickness of the spacer 70 is the direction along the Z-axis. The spacer 70 has a surface facing in the direction Z1 and a surface facing in the direction Z2. The surface of the spacer 70 facing in the direction Z1 is bonded by an adhesive to the housing 50. The surface of the spacer 70 facing in the direction Z2 is bonded by an adhesive to the plurality of insulating substrates 20. The shape of the spacer 70 is not limited to the example shown in FIG. 1 and may be freely selected.

The lid 80 is a plate-shaped member joined to a surface of the housing 50 facing in the direction Z1. The lid 80 is made of a resin material such as a PPS material or a PBT material, as is the housing 50, for example. The lid 80 is bonded to the housing 50 by an adhesive, etc., such that a gap between the lid 80 and the housing 50 is sealed. It should be noted that the lid 80 may be provided, or may be omitted, as appropriate.

The base plate 40, the housing 50, and the lid 80 surround a space. The space surrounded by the base plate 40, the housing 50, and the lid 80 is filled with a potting material that encapsulates the plurality of semiconductor chips 30. The potting material is made of, for example, an epoxy resin or a silicone resin such as a silicone gel material.

### 1-2. External Terminal and Insulating Substrate

FIG. 2 to FIG. 4 are cross sections of the semiconductor module 10 according to this embodiment. In FIG. 2, a connection mode is shown in which an external terminal 60-M1 and a semiconductor chip 30 among the plurality of semiconductor chips 30 are electrically connected to each other. The external terminal 60-M1 is an external terminal 60, which is an input main terminal, among the plurality of external terminals 60. In FIG. 3, a connection mode is shown in which an external terminal 60-M2 and a semiconductor chip 30 among the plurality of semiconductor chips 30 are electrically connected to each other. The external terminal 60-M2 is an external terminal 60, which is an output main terminal, among the plurality of external terminals 60. In FIG. 4, a connection mode is shown in which an external terminal 60-C and a semiconductor chip 30 among the plurality of semiconductor chips 30 are electrically connected to each other. The external terminal 60-C is an external terminal 60, which is a control terminal, among the plurality of external terminals 60. In the following, each of the external terminals 60-M1, 60-M2, and 60-C may be referred to as an external terminal 60 without distinction therebetween. In FIG. 2 to FIG. 4, the shape of the external terminal 60 is simply shown for convenience.

As shown in FIG. 2 to FIG. 4, the insulating substrate 20 includes an insulating board 21, a conductor board 22, and a conductor pattern 23.

The insulating board 21 is an insulating plate-shaped member that is disposed such that a direction of thickness of the insulating board 21 is the direction along the Z-axis. The insulating board 21 is made of, for example, a ceramic material such as an aluminum nitride material, an aluminum oxide material, or a silicon nitride material. As viewed in the direction along the Z-axis, the insulating board 21 extends not only in an area in an inward direction from the housing 50, but also in an area overlapping the housing 50. The insulating board 21 has a surface facing in the direction Z1 and a surface facing in the direction Z2.

The conductor board 22 is a plate-shaped conductor that is disposed on substantially the entire area of the surface of the insulating board 21 facing in the direction Z2. The conductor board 22 is made of, for example, a metallic material such as a copper material or an aluminum material. The conductor board 22 is joined by a joining material BO such as a solder material to the base plate 40.

The conductor pattern 23 is disposed on a surface of the insulating board 21. The conductor pattern 23 includes a conductor 23a joined to the two or more semiconductor chips 30. In this embodiment, the conductor pattern 23 is disposed on the surface of the insulating board 21 facing in the direction Z1. The conductor pattern 23 includes a plurality of conductors 23a, 23b, and 23c that are separate from one another. The conductor pattern 23 is made of, for example, a metallic material such as a copper material or an aluminum material, as is the conductor board 22. The conductor pattern 23 is joined by a joining material such as a solder material to the two or more semiconductor chips 30.

As shown in FIG. 2 and FIG. 3, the conductor 23a is a conductor joined to the two or more semiconductor chips 30, which include semiconductor chips 30 each including the input electrode 30a, the output electrode 30b, and the control electrode 30c. The conductor 23a is electrically connected to the input electrode 30a of each of the semiconductor chips 30. The electrical connection of the conductor 23a and the input electrode 30a of each of the semiconductor chips 30 is carried out by joining the conductor 23a and the input electrode 30a of each of the semiconductor chips 30 to each other with a solder material etc. As shown in FIG. 2, the conductor 23a has a portion that is disposed directly below the external terminal 60-M1. This portion of the conductor 23a is in contact with a connector 63 of the external terminal 60-M1. The connector 63 of the external terminal 60-M1 is described below.

As shown in FIG. 3, the conductor 23b is a conductor that is not joined to any semiconductor chip 30. The conductor 23b is electrically connected to the output electrode 30b of each of the semiconductor chips 30. The electrical connection of the conductor 23b and the output electrode 30b of each of the semiconductor chips 30 is carried out by a bonding wire BW1 connecting the conductor 23b and the output electrode 30b of each of the semiconductor chips 30 to each other. The conductor 23b has a portion that is disposed directly below the external terminal 60-M2. This portion of the conductor 23b is in contact with a connector 63 of the external terminal 60-M2. The connector 63 of the external terminal 60-M2 is described below.

As shown in FIG. 4, the conductor 23c is a conductor that is not joined to any semiconductor chip 30. The conductor 23c has a portion that is disposed directly below the external terminal 60-C. This portion of the conductor 23c is in contact with a connector 63 of the external terminal 60-C. The connector 63 of the external terminal 60-C is described below.

An external terminal 60 used as any one of the external terminals 60-M1, 60-M2, and 60-C is made of a metallic plate that has an L-shape schematically. More specifically, as shown in FIG. 2 to FIG. 4, the external terminal 60 includes a pin 61, a leg 62, and the connector 63.

The pin 61 is a portion of the external terminal 60. The pin 61 has a shape of a bar. The pin 61 extends toward the outside of the housing 50 along the direction of thickness of the insulating substrate 20. In each of the examples shown in FIG. 2 to FIG. 4, the pin 61 extends in the direction along the Z-axis. The pin 61 has an end in the direction Z1 and an end in the direction Z2. The end of the pin 61 in the direction Z1 protrudes from an outer wall surface of the housing 50. Thus, the pin 61 includes a terminal portion that protrudes from the outer wall surface of the housing 50. The terminal portion is connected to the substrate (not shown) to be provided with the semiconductor module 10. The pin 61 described above is connected to the leg 62 and to the connector 63.

The leg 62 is a portion of the external terminal 60. The leg 62 has a shape of a plate. The leg 62 extends toward the inside of the housing 50 along a direction intersecting a direction of extension of the pin 61. In this embodiment, the leg 62 is disposed on, and is disposed along, the surface of the spacer 70 facing in the direction Z1. The leg 62 extends from the end of the pin 61 that is in the direction Z2 toward the inside of the housing 50. The leg 62 includes a portion interposed between the housing 50 and the spacer 70, and a pad that is exposed in a space in the inward direction from the housing 50. As shown in FIG. 4, the pad of the external terminal 60-C is joined to one end of a bonding wire BW2. The other end of the bonding wire BW2 is joined to the control electrode 30c of a corresponding semiconductor chip 30 among the semiconductor chips 30. As described above, the external terminal 60-C and the control electrode 30c of the corresponding semiconductor chip 30 are electrically connected to each other via the bonding wire BW2. In other words, the external terminal 60-C that is a control terminal is electrically connected to the control electrode 30c of the corresponding semiconductor chip 30 via the bonding wire BW2 that is joined to the leg 62 of the corresponding semiconductor chip 30.

It should be noted that the other end of the bonding wire BW2 may be joined to a conductor, which is electrically connected to the control electrode 30c of the corresponding semiconductor chip 30, among a plurality of conductors included in the conductor pattern 23 of the insulating substrate 20. The pad of the external terminal 60-M1 may be joined to one end of a bonding wire, as appropriate. In this case, the other end of the bonding wire is joined to the conductor 23a, or to a conductor that is electrically connected to the conductor 23a, among the plurality of conductors included in the conductor pattern 23 of the insulating substrate 20. Similarly, the pad of the external terminal 60-M2 may be joined to one end of a bonding wire, as appropriate. In this case, the other end of the bonding wire is joined to the output electrode 30b of the corresponding semiconductor chip 30, or to a conductor, which is electrically connected to the output electrode 30b of the corresponding semiconductor chip 30, among the plurality of conductors included in the conductor pattern 23 of the insulating substrate 20.

The surface of the spacer 70 facing in the direction Z1 is bonded by an adhesive (not shown) to a surface of the leg 62 facing in the direction Z2 and to the housing 50. The surface of the spacer 70 facing in the direction Z2 is bonded by an insulating adhesive B1 to the surface of the insulating substrate 20 facing in the direction Z1. The base plate 40 and the housing 50 are bonded by an insulating adhesive B2 to each other. Each of the adhesive B1 and the adhesive B2 is, for example, a silicone adhesive or an epoxy adhesive including an inorganic filler such as a silica material or an alumina material. The adhesive B1 and the adhesive B2 may be of the same type or be of a different type. The adhesive B1 and the adhesive B2 may be continuous with each other.

As described above, the insulating spacer 70 is interposed between the leg 62 and the insulating substrate 20. Thus, it is possible to ensure necessary electrical insulation between the external terminal 60 and the conductor pattern 23 and to firmly fix the external terminal 60 to the housing 50. It should be noted that the spacer 70 may be provided, or may be omitted, as appropriate.

The connector 63 is a portion of the external terminal 60. The connector 63 extends from the pin 61 toward the insulating substrate 20 along the direction of thickness of the insulating substrate 20. In each of the examples shown in FIG. 2 to FIG. 4, the connector 63 protrudes in the direction Z2 from the pin 61. A length of protrusion of the connector 63 is greater than a thickness of the spacer 70. Thus, the end of the connector 63 in the direction Z2 is disposed in the direction Z2 from the spacer 70. In addition, the end of the connector 63 in the direction Z2 is in contact with the conductor pattern 23 of the insulating substrate 20. More specifically, as shown in FIG. 2, in the external terminal 60-M1, the end of the connector 63 in the direction Z2 is in contact with the conductor 23a described above. As shown in FIG. 3, in the external terminal 60-M2, the end of the connector 63 in the direction Z2 is in contact with the conductor 23b described above. As shown in FIG. 4, in the external terminal 60-C, the end of the connector 63 in the direction in Z2 is in contact with the conductor 23c described above.

The connector 63 is in contact with the conductor pattern 23 in a state in which the connector 63 receives compression force from the insulating substrate 20 and the housing 50. Thus, it is possible to electrically connect the external terminal 60 the conductor pattern 23. Consequently, it is possible to reduce the number of bonding wires for electrically connecting the external terminal 60 and the corresponding semiconductor chip 30.

Specifically, in a state in which a bonding wire joined to the external terminal 60-M1 and to the insulating substrate 20 is not provided, the contact between the connector 63 of the external terminal 60-M1 and the conductor 23a allows the external terminal 60-M1 and the input electrode 30a of the corresponding semiconductor chip 30 to be electrically connected to each other. In addition, in a state in which a bonding wire joined to the external terminal 60-M2 and to the insulating substrate 20 is not provided, the contact between the connector 63 of the external terminal 60-M2 and the conductor 23b allows the external terminal 60-M2 and the output electrode 30b of the corresponding semiconductor chip 30 to be electrically connected to each other. However, a bonding wire may be provided that is joined to the insulating substrate 20 and to either the external terminal 60-M1 or the external terminal 60-M2. In this case, the contact between the connector 63 and the conductor pattern 23 ensures a main current path. Thus, it is possible to reduce the number of bonding wires compared to a configuration in which the connector 63 is not provided.

As described above, the connector 63 of the external terminal 60-M1, which is a main terminal that is to be electrically connected to the main current path in the corresponding semiconductor chip 30, is in contact with the conductor 23a, which is electrically connected to the main current path in the corresponding semiconductor chip 30, among the plurality of conductors 23a, 23b, and 23c. Similarly, the connector 63 of the external terminal 60-M2, which is a main terminal that is to be electrically connected to the main current path in the corresponding semiconductor chip 30, is in contact with the conductor 23b, which is electrically connected to the main current path in the corresponding semiconductor chip 30, among the plurality of conductors 23a, 23b, and 23c. The contact between the conductor pattern 23 and both the external terminal 60-M1 and the external terminal 60-M2 described above allows reduction in the number of bonding wires and allows each of the external terminal 60-M1 and the external terminal 60-M2 to be electrically connected to the main current path in the corresponding semiconductor chip 30.

In addition, the insulating substrate 20 extends directly below the connector 63 of the external terminal 60. Thus, the extension of the insulating substrate 20, together with the reduction in the number of bonding wires, allows a space for accommodating the plurality of semiconductor chips 30 to be sufficiently ensured over the insulating substrate 20 compared to a configuration in which the connector 63 is not provided. Consequently, it is possible to reduce a size of the housing 50 and to increase a size of each of the plurality of semiconductor chips 30. As a result, it is possible to reduce a size of the semiconductor module 10 and to increase a rated current of the semiconductor module 10.

In addition, it is possible to efficiently conduct heat, which is generated by the external terminal 60 through which a current passes, from the connector 63 through the insulating substrate 20 to the base plate 40. Thus, it is possible to increase a current that is permitted to flow into each of the plurality of external terminals 60. As a result, in a state in which the number of external terminals 60 is not increased, it is possible to increase the rated current of the semiconductor module 10. In addition, it is possible to use a space obtained by reducing the number of external terminals 60 to add a function to the semiconductor module 10. For example, it is possible to add an auxiliary emitter terminal and an auxiliary collector terminal. Alternatively, in a state in which a built-in shunt resistor is included, it is possible to add a terminal for sensing a resistance value of the shunt resistor.

In addition, the connector 63 of the external terminal 60-C, which is a control terminal, is in contact with the conductor 23c, which differs from the conductors 23a and 23b that are each electrically connected to the main current path in the corresponding semiconductor chip 30, among the plurality of conductors 23a, 23b, and 23c. Thus, it is possible to prevent complication of the conductor pattern 23 and to electrically connect the external terminal 60-C to the corresponding semiconductor chip 30. Here, a current capacity of the external terminal 60-C, which is the control terminal, is significantly less than a current capacity of each of the external terminals 60-M1 and 60-M2 that are the main terminals. Thus, it is possible to reduce the number of bonding wires BW2. The connector 63 receives compression force from the insulating substrate 20 and the housing 50. Thus, it is possible to stabilize the contact between the connector 63 and the conductor pattern 23.

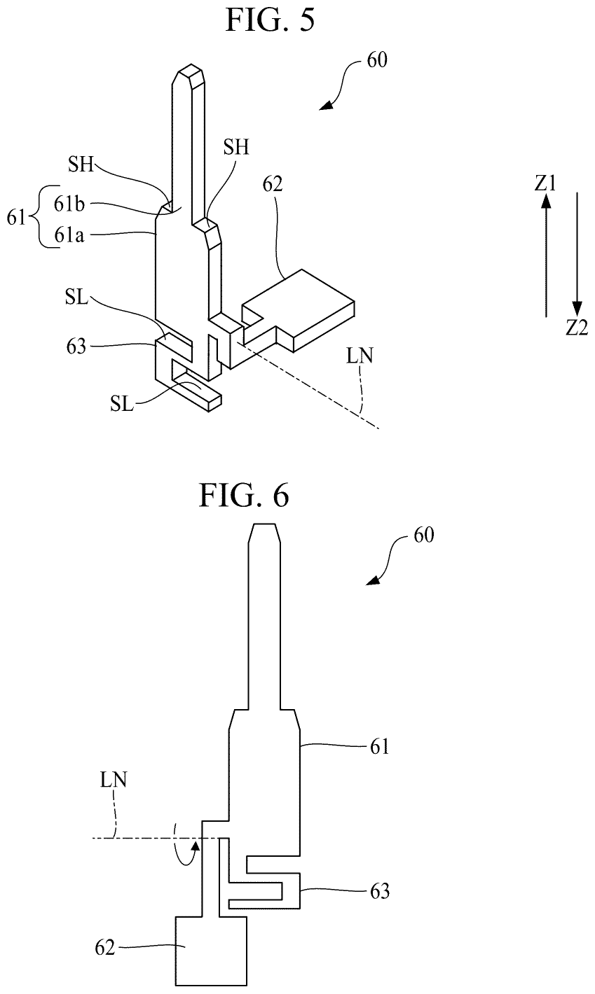

FIG. 5 is a perspective view of the external terminal 60 according to this embodiment. FIG. 6 is a diagram explaining an example of a method for producing the external terminal 60. FIG. 5 shows an example of the external terminal 60 produced by bending a metallic plate. FIG. 6 shows a state in which the external terminal 60 is not yet bent.

As shown in FIG. 5, the pin 61 includes a first portion 61a and a second portion 61b. The first portion 61a is a portion of the pin 61. The first portion 61a is accommodated in a corresponding terminal hole 51 among the plurality of terminal holes 51 of the housing 50. The first portion 61a has an end in the direction Z1 and an end in the direction Z2. The second portion 61b is a portion of the pin 61. The second portion 61b extends in the direction Z1 from the end of the first portion 61a in the direction Z1. The second portion 61b includes the terminal portion that protrudes in an outward direction from the housing 50. A width of the second portion 61b is less than a width of the first portion 61a. Thus, the first portion 61a includes a pair of shoulders SH that are each constituted of a surface facing in the direction Z1. Although not shown, the corresponding terminal hole 51 includes a pair of surfaces that is in contact with the pair of shoulders SH. Thus, the connector 63 of the external terminal 60 receives compression force from the housing 50 and the insulating substrate 20.

The shape of the pin 61 is not limited to the example shown in each of FIG. 5 and FIG. 6. For example, the shape of the pin 61 may be such that the second portion 61b branches into two parts.

A side surface of the first portion 61a includes an area that is connected to the leg 62. The area that is connected to the leg 62 is disposed in a vicinity of the end of the first portion 61a in the direction Z2. In this embodiment, the external terminal 60 is produced by bending a metallic plate. The external terminal 60 is bent along a bend line LN intersecting the Z-axis such that the leg 62 extends the direction intersecting the direction of extension of the pin 61. The shape of the leg 62 is not limited to the example shown in FIG. 5 and may have a shape with a constant width.

The end of the first portion 61a in the direction Z2 is connected to the connector 63. As shown in FIG. 5, the connector 63 has a shape of a spring elastically deformable in the direction along the Z-axis. In other words, the connector 63 has a shape of a spring elastically deformable in the direction of thickness of the insulating substrate 20. Thus, it is possible to prevent an occurrence of pressure that causes cracks of the insulating substrate 20 and to maintain a stable contact between the conductor pattern 23 and the connector 63.

The connector 63 is provided with a plurality of slits SL extending in a direction intersecting the direction of thickness of the insulating substrate 20. Thus, it is possible to easily produce the external terminal 60 having the spring-shaped connector 63 by punching a metallic plate, for example.

In the example shown in FIG. 5, the two slits SL are arranged in the direction along the Z-axis. One of the two slits SL includes an opening in a first direction along the direction along the Z-axis. The other of the two slits SL includes an opening in a second direction opposite to the first direction. The number of slits SL is not limited to the example shown in FIG. 5 and may be one, or may be three or more. A direction of extension of the slits SL is not limited to a direction perpendicular to the Z-axis and may be a direction inclined relative to the direction perpendicular to the Z-axis, for example. The shape of each of the slits SL is not limited to the example shown in FIG. 5, and may be a curved shape or may be a shape that does not have a constant width, for example.

An external terminal 60, which has been produced by punching a metallic plate, is inserted into the corresponding terminal hole 51 of the housing 50. After an adhesive is applied to the surface of the leg 62 facing in the direction Z2, the spacer 70 is fitted into the space in the inward direction from the housing 50. Thus, the external terminal 60 is fixed to the housing 50.

The base plate 40, the plurality of semiconductor chips 30, and the plurality of insulating substrates 20 are laminated by soldering to produce a laminate. This laminate is adhered to the housing 50 in a state in which the laminate is inserted into the space in the inward direction from the housing 50 that is provided with the plurality of external terminals 60 and the spacer 70 described above. This adhesion is carried out in a state in which pressure is applied between the housing 50 and the base plate 40. Thus, it is possible to fix the plurality of external terminals 60 to the plurality of insulating substrates 20 in a state in which the plurality of external terminals 60 is pressed against the plurality of insulating substrates 20. Here, as described above, the connector 63 has a shape of a spring. Thus, the connector 63 is appropriately deformed in accordance with pressing of the base plate 40 against the housing 50.

Thereafter, wire bonding is appropriately carried out in the space in the inward direction from the housing 50. Next, the space in the inward direction from the housing 50 is filled with a potting material. Next, the lid 80 is adhered to the housing 50. Thus, the semiconductor module 10 is produced.

As described above, in the semiconductor module 10, the connector 63 of the external terminal 60 is in contact with the conductor pattern 23. Thus, it is possible to reduce the number of bonding wires for electrically connecting the external terminal 60 and the corresponding semiconductor chip 30. In addition, this reduction in the number of bonding wires, together with the insulating substrate 20 extending directly below the connector 63 of the external terminal 60, allows reduction in a size of the semiconductor module 10 and an increase in the rated current of the semiconductor module 10. In addition, it is possible to efficiently conduct heat, which is generated by an external terminal 60 through which a current passes, from the connector 63 through the insulating substrate 20 to the base plate 40. Thus, in a state in which the number of external terminals 60 is not increased, it is possible to increase the rated current of the semiconductor module 10.

### 2. Modifications

This disclosure is not limited to the embodiments described above, and various modifications described below can be made thereto. In addition, each of the embodiments and each of the modifications may be combined with others as appropriate.

### 2-1. First Modification

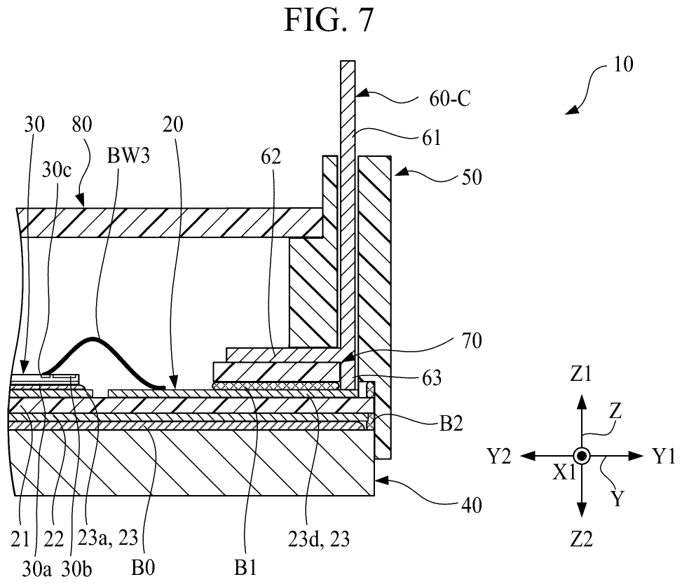

FIG. 7 is a cross section of a semiconductor module 10 according to a first modification. In FIG. 7, another example of the connection mode is shown in which the external terminal 60-C and the semiconductor chip 30 are electrically connected to each other.

When two or more control terminals are provided, the connection mode shown in FIG. 4 and the connection mode shown in FIG. 7 may be used as appropriate. In the connection mode shown in FIG. 7, the conductor pattern 23 includes not only the plurality of conductors 23a, 23b, and 23c described above, but also a conductor 23d. It should be noted that the connection mode shown in FIG. 7 may be used in place of the connection mode shown in FIG. 4.

As shown in FIG. 7, the conductor 23d is a conductor that is not joined to any of the plurality of semiconductor chips 30. The conductor 23d is electrically connected to the control electrode 30c of each of the semiconductor chips 30. The electrical connection of the conductor 23d and the control electrode 30c of each of the semiconductor chips 30 is carried out by a bonding wire BW3 connecting the conductor 23d and the control electrode 30c of each of the semiconductor chips 30 to each other. The conductor 23d has a portion that is disposed directly below the external terminal 60-C. This portion of the conductor 23d is in contact with the connector 63 of the external terminal 60-C.

According to the first modification, it is possible to reduce a size of the semiconductor module 10 and to increase a rated current of the semiconductor module 10.

### 2-2. Second Modification

In the above-described embodiment, a configuration is described in which each of the plurality of external terminals 60 included in the semiconductor module 10 includes the connector 63. However, this disclosure is not limited to this configuration. The semiconductor module 10 may include an external terminal having no connector 63. The external terminal having no connector 63 is not particularly limited and may be a well-known external terminal.

### 2-3. Third Modification

In the above-described embodiment, a configuration is described in which the external terminal 60 is produced by punching a metallic plate. However, this disclosure is not limited to this configuration. For example, the external terminal 60 may be produced in a method in which the pin 61 is joined by welding to one or both of the leg 62 and the connector 63 that have been produced in a different process from a process of producing the pin 61. In this case, it is possible to cause a state in which a location of a central axis of the connector 63 in a direction of width of the connector 63 and a location of a central axis of the pin 61 in a direction of width of the pin 61 are the same.

### 3. Supplemental Notes

The following configurations are derivable from this embodiment or from the modifications described above, for example.

A semiconductor module according to one aspect (first aspect) of this disclosure includes a base plate; an insulating substrate disposed on a surface of the base plate and provided with a semiconductor chip; a housing having a shape of a frame surrounding the insulating substrate; and a plurality of external terminals each having a portion disposed in the housing and a portion protruding from the housing, the plurality of external terminals being electrically connected to the semiconductor chip, wherein the insulating substrate includes an insulating board; and a conductor pattern disposed on a surface of the insulating board and including a conductor joined to the semiconductor chip, wherein at least one external terminal of the plurality of external terminals includes a pin extending toward an outside of the housing along a direction of thickness of the insulating substrate; a leg extending toward an inside of the housing along a direction intersecting a direction of extension of the pin; and a connector extending from the pin toward the insulating substrate along the direction of thickness of the insulating substrate, and wherein the connector is in contact with the conductor pattern in a state in which the connector receives compression force from the insulating substrate and the housing.

According to this aspect, the connector of the external terminal is in contact with the conductor pattern in a state in which the connector receives compression force from the insulating substrate and the housing. Thus, it is possible to electrically connect the external terminal to the conductor pattern. Consequently, it is possible to reduce the number of bonding wires for electrically connecting the external terminal and the semiconductor chip.

In addition, the insulating substrate extends directly below the connector of the external terminal. Thus, the extension of the insulating substrate, together with the reduction in the number of bonding wires, allows reduction in a size of the housing and an increase in a size of the semiconductor chip. Thus, it is possible to reduce a size of the semiconductor module and to increase a rated current of the semiconductor module.

In addition, it is possible to efficiently conduct heat, which is generated by the external terminal through which a current passes, from the connector through the insulating substrate to the base plate. Thus, it is possible to increase a current that is permitted to flow into each of the plurality of external terminals. As a result, in a state in which the number of external terminals is not increased, it is possible to increase the rated current of the semiconductor module.

In an example (second aspect) of the first aspect, the semiconductor chip includes a control electrode, the at least one external terminal includes an external terminal that is a control terminal electrically connected to the control electrode via a bonding wire joined to the leg, the conductor pattern includes a plurality of conductors separated from each other, and the connector included in the control terminal is in contact with a different conductor from a conductor electrically connected to a main current path in the semiconductor chip among the plurality of conductors.

According to this aspect, it is possible to prevent complication of the conductor pattern and to electrically connect the control terminal to the semiconductor chip. Here, a current capacity of the control terminal is significantly less than a current capacity of a main terminal. Thus, it is possible to reduce the number of bonding wires. The connector of the control terminal is in contact with the conductor that differs from the conductor electrically connected to the main current path in the semiconductor chip. Thus, the connector of the control terminal can ensure functions of the control terminal appropriately and can contribute to dissipation of heat from the control terminal and another external terminal.

In an example (third aspect) of the first or second aspect, the at least one external terminal includes an external terminal that is a main terminal electrically connected to a main current path in the semiconductor chip, the conductor pattern includes a plurality of conductors separated from each other, and the connector included in the main terminal is in contact with a conductor electrically connected to the main current path in the semiconductor chip among the plurality of conductors.

According to this aspect, it is possible to reduce the number of bonding wires and to electrically connect the main terminal to the main current path in the semiconductor chip.

In an example (fourth aspect) of any of the first to third aspects, the connector has a shape of a spring elastically deformable in the direction of thickness of the insulating substrate.

According to this aspect, it is possible to prevent pressure that causes cracking of the insulating substrate and to maintain stable contact between the conductor pattern and the connector.

In an example (fifth aspect) of the fourth aspect, the connector is provided with a slit extending in a direction intersecting the direction of thickness of the insulating substrate.

According to this aspect, it is possible to easily produce the external terminal having the spring-shaped connector by punching a metallic plate, for example.

In an example (sixth aspect) of any of the first to fifth aspects, the semiconductor module further comprising an insulating spacer interposed between the leg and the insulating substrate.

According to this aspect, it is possible to ensure necessary electrical insulation between the external terminal and the conductor pattern and to stably fix the external terminal to the housing.

### DESCRIPTION OF REFERENCE SIGNS

10 . . . semiconductor module, 20 . . . insulating substrate, 21 . . . insulating board, 22 . . . conductor board, 23 . . . conductor pattern, 23a . . . conductor, 23b . . . conductor, 23c . . . conductor, 23d . . . conductor, 30 . . . semiconductor chip, 40 . . . base plate, 41 . . . mounting hole, 50 . . . housing, 51 . . . terminal hole, 52 . . . hole, 53 . . . hole, 60 . . . external terminal, 60-C . . . external terminal, 60-M . . . external terminal, 60-M1 . . . external terminal, 60-M2 . . . external terminal, 61 . . . pin, 61a . . . first portion, 61b . . . second portion, 62 . . . leg, 63 . . . connector, 70 . . . spacer, 80 . . . lid, BO . . . joining material, B1 . . . adhesive, B2 . . . adhesive, BW1 . . . bonding wire, BW2 . . . bonding wire, BW3 . . . bonding wire, LN . . . bend line, SH . . . shoulder, SL . . . slit.

What is claimed is:

1. A semiconductor module comprising:
a base plate;
an insulating substrate disposed on a surface of the base plate and provided with a semiconductor chip;
a housing having a shape of a frame surrounding the insulating substrate; and
a plurality of external terminals each having a portion disposed in the housing and a portion protruding from the housing, the plurality of external terminals being electrically connected to the semiconductor chip,
wherein the insulating substrate includes:
an insulating board; and
a conductor pattern disposed on a surface of the insulating board and including a conductor joined to the semiconductor chip,
wherein at least one external terminal of the plurality of external terminals includes:
a pin extending toward an outside of the housing along a direction of thickness of the insulating substrate;
a leg extending toward an inside of the housing along a direction intersecting a direction of extension of the pin; and
a connector extending from the pin toward the insulating substrate along the direction of thickness of the insulating substrate, and
wherein the connector is in contact with the conductor pattern in a state in which the connector receives compression force from the insulating substrate and the housing.

2. The semiconductor module according to claim 1,
wherein the semiconductor chip includes a control electrode,
wherein the at least one external terminal includes an external terminal that is a control terminal electrically connected to the control electrode via a bonding wire joined to the leg,
wherein the conductor pattern includes a plurality of conductors separated from each other, and
wherein the connector included in the control terminal is in contact with a different conductor from a conductor electrically connected to a main current path in the semiconductor chip among the plurality of conductors.

3. The semiconductor module according to claim 1,
wherein the at least one external terminal includes an external terminal that is a main terminal electrically connected to a main current path in the semiconductor chip, wherein the conductor pattern includes a plurality of conductors separated from each other, and
wherein the connector included in the main terminal is in contact with a conductor electrically connected to the main current path in the semiconductor chip among the plurality of conductors.

4. The semiconductor module according to claim 1, wherein the connector has a shape of a spring elastically deformable in the direction of thickness of the insulating substrate.

5. The semiconductor module according to claim 4, wherein the connector is provided with a slit extending in a direction intersecting the direction of thickness of the insulating substrate.

6. The semiconductor module according to claim 1, further comprising an insulating spacer interposed between the leg and the insulating substrate.
